(19) United States
(12) Patent Application Publication
(10) Pub. No.: US 2024/0006523 A1
(43) Pub. Date: Jan. 4, 2024

(54) FIELD EFFECT TRANSISTOR DEVICE

(71) Applicant: HUAWEI TECHNOLOGIES CO., LTD., Shenzhen (CN)

(72) Inventor: Samir MOUHOUBI, Nuremberg (DE)

(21) Appl. No.: 18/467,911

(22) Filed: Sep. 15, 2023

Related U.S. Application Data
(63) Continuation of application No. PCT/EP2021/056856, filed on Mar. 17, 2021.

(51) Int. Cl. H01L 29/778; H01L 29/20; H01L 29/08; H01L 21/02

(52) U.S. Cl. CPC H01L 29/7781; H01L 29/2003; H01L 29/0891; H01L 21/02458; H01L 29/7783; H01L 21/02389

(57) ABSTRACT

The present disclosure relates to a FET device (10), comprising a substrate (11), a GaN structure (15) covering a portion of the substrate (11), and a gate metal layer (17) on top of the GaN structure (15). The gate metal layer (17) comprises at least one first section (17-1) being formed from a first material composition, and a second section (17-2) being formed from a second material composition that is different from the first material composition, wherein a first interface (41) between the GaN structure (15) and the at least one first section (17-1) of the gate metal layer (17) has ohmic contact properties, and wherein a second interface (43) between the GaN structure (15) and the second section (17-2) of the gate metal layer (17) has non-ohmic contact properties

### CROSS-REFERENCE TO RELATED APPLICATIONS

This application is a continuation of International Application No. PCT/EP2021/056856, filed on Mar. 17, 2021, the disclosure of which is hereby incorporated by reference in its entirety.

### TECHNICAL FIELD

The present disclosure relates to a field effect transistor (FET) device and, in particular, to a high electron mobility transistor (HEMT) device. The present disclosure further relates to a method of fabricating such a FET device.

### BACKGROUND

Field effect transistors (FETs) are key components for many electronic devices. FETs, generally, comprise the three components: source, gate and drain. By applying a voltage to the gate, a current flow between the source and drain can be controlled.

High-electron-mobility transistors, so called HEMTs, are special types of FETs that have a channel that is formed by a heterojunction, i.e. a junction between two materials with different band gaps. There are different material combinations that can be used to form the heterojunction, such as AlGaAs/GaAs or AlGaN/GaN.

The HEMT market is dominated by two technology concepts: the ohmic gate concept and the Schottky gate concept. Thereby, the terms ohmic gate and Schottky gate refer to the interface between a gate structure and a metallic gate contact of the HEMT. Both concepts suffer from inherent limitations and technological issues. The main difference between the two concepts is the gate current, which is low in the case of a Schottky contact and high in the case of an ohmic contact. The choice of one of these concepts has a strong influence on the electrical characteristics of the HEMT, e.g. its voltage class, its resistance class or its reliability requirements, and, thus, limits the kind of devices that can be built with a certain HEMT.

FIG. 1 shows an example of a gallium nitride (GaN) HEMT structure according to a conventional example. This HEMT structure comprises an aluminum gallium nitride (AlGaN) layer on top of a substrate. A gallium nitride GaN layer is arranged on top of the AlGaN layer and is contacted by a gate metal layer. The GaN layer and the AlGaN layer form a specific part of the HEMT that can be modeled to either form an ohmic contact or a Schottky contact.

FIG. 2a shows an equivalent circuit diagram of the gate of the GaN HEMT from FIG. 1 with an ohmic contact. A HEMT with such an ohmic gate has the advantage that the voltage of the mid-node (Vm) is directly controlled by the applied gate voltage (Vg) and, thus, no floating region exists in the GaN layer. Furthermore, it is possible to evacuate carriers in both positive and negative biasing, allowing for a robust and stable gate with good dynamic and long term performance. However, the current that is needed to drive the gate can be large which causes a high current consumption in the full system, requiring complex driving design schemes.

FIG. 2b shows an equivalent circuit diagram of the gate of the GaN HEMT from FIG. 1 with a Schottky contact. A HEMT with such a Schottky gate has the advantage that the gate current can be reduced due to the possibility of reverse biasing the Schottky contact between the applied gate voltage (Vg) and the mid-node voltage (Vm). As a consequence, an easier driving mode can be chosen and the scalability, e.g., with regard to voltage class and resistance class, is enhanced. However, the mid-node voltage (Vm) is electrically floating, which might cause a poor dynamic performance. Further, the depletion at the Schottky contact can lead to a reduced gate reliability.

In summary, the ohmic gate is a robust and reliable concept for high voltage class devices but less suitable for low voltage and/or low switch-on resistance (Ron) devices. The Schottky gate, on the other hand, is more suitable for low voltage and/or low Ron devices but has inherent weaknesses. It is difficult and costly to develop different types of HEMTs with these two technologies and properties in parallel. Thus, there is a need for improved FET devices and, improved HEMT devices.

### SUMMARY

In view of the above-mentioned problems and disadvantages, the present disclosure aims to improve field effect transistor devices, in particular HEMT devices, and their fabrication methods. The present disclosure has thereby the object to provide for an improved field effect transistor device.

The object of the present disclosure is achieved by the embodiments provided in the enclosed independent claims. Advantageous implementations of the present disclosure are further defined in the dependent claims.

According to a first aspect, a field effect transistor (FET) device is provided, comprising: a substrate; a gallium nitride (GaN) structure covering a portion of the substrate; and a gate metal layer on top of the GaN structure; wherein the gate metal layer comprises: at least one first section being formed from a first material composition, and a second section being formed from a second material composition that is different from the first material composition; wherein a first interface between the GaN structure and the at least one first section of the gate metal layer has ohmic contact properties; and wherein a second interface between the GaN structure and the second section of the gate metal layer has non-ohmic contact properties.

This achieves the advantage that a FET device with a hybrid gate is formed, which has electrical properties that combine aspects of an ohmic gate and a non-ohmic gate, e.g. a Schottky gate. In particular, gate properties, such as the gate current level, can be controlled by the aspect ratio between the at least one first section of the gate metal layer and the second section of the gate metal layer, i.e. by the aspect ratio between interfaces with ohmic and non-ohmic contact properties.

The substrate may comprise a base structure with one or more layers on top. In particular, the substrate comprises an aluminum gallium nitride (AlGaN) top layer. The GaN structure can be arranged on top of the AlGaN layer. A channel can be formed below the AlGaN layer in a region under the GaN structure.

Further, source and drain structures of the FET device can be arranged on both ends of the GaN structure.

In an implementation form of the first aspect, the first interface forms an ohmic contact, and the second interface forms a Schottky junction or a p-n junction.

In particular, the ohmic contact of the first interface can also be formed by a tunneling junction or a quasi-ohmic contact between the GaN structure and the gate metal layer.

In an implementation form of the first aspect, the first interface makes up less than 10%, in particular less than 5%, more particular less than 1%, of a total interface area between the GaN structure and the gate metal layer, the total interface area comprising the first interface and the second interface. This achieves the advantage that the electrical properties of the gate, e.g. a gate current, can be adjusted efficiently.

For example, by reducing the portion of the ohmic interface on the total interface, a gate current of the FET device is reduced.

In an implementation form of the first aspect, the gate metal layer comprises a plurality of first sections that are separated from each other.

In particular, the plurality of first sections can be distributed across the gate area.

In an implementation form of the first aspect, the gate metal layer comprises a separating layer that is arranged around the at least one first section of the gate metal layer to physically separate the first section from the second section of the gate metal layer.

The separating layer can be formed from an insulating material. For instance, the separating layer is a dielectric.

In an implementation form of the first aspect, the at least one first section of the gate metal layer has a bigger thickness than the second section. This achieves the advantage that the electrical properties of the first and/or second interface can be further adjusted.

For example, the first section of the gate metal layer protrudes from the second section and can partially covers a top side of said second section. This can make it easier to electrically contact the first section.

In an implementation form of the first aspect, the at least one first section of the gate metal layer is formed from a first metal stack, and/or the second section of the gate metal layer is formed from a second metal stack.

In an implementation form of the first aspect, the first metal stack and/or the second metal stack comprises any one of the following material combinations: Ni/Au, Ni/Ag, Pd/Au, Cr/Au, Pt/Au, Ti/Pt/Au, Ni/Si, W/Si, Ti/A1, Ti/Al/Ti, or TiN/Al/TiN.

In an implementation form of the first aspect, the GaN structure comprises a p-doped GaN, pGaN, layer.

In an implementation form of the first aspect, the GaN structure comprises an n-doped GaN, nGaN, layer that is arranged above of the pGaN layer, wherein the nGaN layer at least partially covers the pGaN layer.

By adding the pGaN and/or the nGaN layers, the electrical properties of the first and/or second interface can be further adjusted. For example, if the nGaN layer is arranged below the second section of the gate metal layer, a Schottky junction formed by the second interface can be changed to a p-n junction.

In an implementation form of the first aspect, the nGaN layer is arranged above the pGaN layer below the first section and the second section of the gate metal layer, such that the first section and the second section of the gate metal layer are physically separated from the pGaN layer. This achieves the advantage that the electrical properties of the first and the second interface can be adjusted.

In an implementation form of the first aspect, the nGaN layer is only arranged above the pGaN layer below the at least one first section of the gate metal layer, or the nGaN layer is only arranged above the pGaN layer below the second section of the gate metal layer. This achieves the advantage that only the electrical properties of one of the two interfaces is further adjusted, while the other interface is not affected.

Alternatively, it is also possible to generate hybrid gate structures by partially covering the first and/or second section with the nGaN layer.

In an implementation form of the first aspect, the FET device is a GaN-gate high electron mobility transistor (HEMT) device.

According to a second aspect, a method of fabricating an FET device is provided, comprising the steps of:
providing a substrate;
forming a gallium nitride, GaN, structure on top of the substrate,
forming a gate metal layer on top of the GaN structure, wherein the gate metal layer comprises at least one first section being formed from a first material composition, and a second section being formed from a second material composition that is different from the first material composition;

wherein a first interface between the GaN structure and the at least one first section of the gate metal layer has ohmic contact properties; and wherein a second interface between the GaN structure and the second section of the gate metal layer has non-ohmic contact properties.

This achieves the advantage that a FET device with a hybrid gate is formed, which has electrical properties that combine aspects of an ohmic gate and a non-ohmic gate, e.g. a Schottky gate. In particular, the gate properties, such as the gate current level, can be controlled by the aspect ratio between the at least one first section of the gate metal layer and the second section of the gate metal layer, i.e. by the aspect ratio between the interfaces with ohmic and non-ohmic contact properties.

In an implementation form of the second aspect, the at least one first section of the gate metal layer is formed from a first metal stack, and/or the second section of the gate metal layer is formed from a second metal stack.

In an implementation form of the second aspect, the first metal stack and/or the second metal stack comprises any one of the following material combinations: Ni/Au, Ni/Ag, Pd/Au, Cr/Au, Pt/Au, Ti/Pt/Au, Ni/Si, W/Si, Ti/A1, Ti/Al/Ti, or TiN/Al/TiN.

In an implementation form of the second aspect, the first interface forms an ohmic contact, and/or the second interface forms a Schottky junction or a p-n junction.

In an implementation form of the second aspect, the first interface makes up less than 10%, in particular less than 5%, more particular less than 1%, of a total interface area between the GaN structure and the gate metal layer, the total interface area comprising the first interface and the second interface.

In an implementation form of the second aspect, the gate metal layer comprises a plurality of first sections that are separated from each other.

In an implementation form of the second aspect, the gate metal layer comprises a separating layer that is arranged around the at least one first section of the gate metal layer to physically separate the first section from the second section of the gate metal layer.

In an implementation form of the second aspect, the at least one first section of the gate metal layer has a bigger thickness than the second section.

In an implementation form of the second aspect, the GaN structure comprises a p-doped GaN, pGaN, layer.

In an implementation form of the second aspect, the GaN structure comprises an n-doped GaN, nGaN, layer that is arranged above of the pGaN layer, wherein the nGaN layer at least partially covers the pGaN layer.

In an implementation form of the second aspect, the nGaN layer is arranged above the pGaN layer below the first section and the second section of the gate metal layer, such that the first section and the second section of the gate metal layer are physically separated from the pGaN layer.

In an implementation form of the second aspect, the nGaN layer is only arranged above the pGaN layer below the at least one first section of the gate metal layer, or the nGaN layer is only arranged above the pGaN layer below the second section of the gate metal layer.

In an implementation form of the second aspect, the FET device is a GaN-gate high electron mobility transistor (HEMT) device.

It has to be noted that all devices, elements, units and means described in the present application could be implemented in the software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof.

### BRIEF DESCRIPTION OF DRAWINGS

The above described aspects and implementation forms of the present disclosure will be explained in the following description of specific embodiments in relation to the enclosed drawings, in which:

FIG. 1 shows an example of a HEMT structure according to a conventional example;

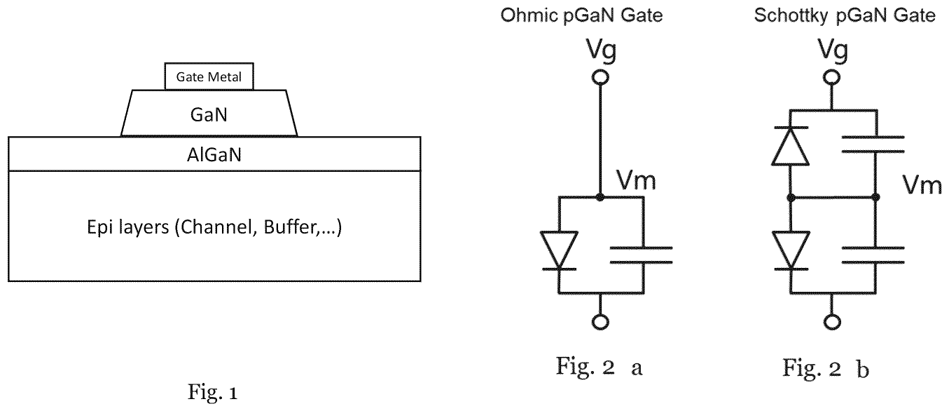

FIGS. 2a-b show equivalent circuit diagrams of a gate of the HEMT structure from FIG. 1;

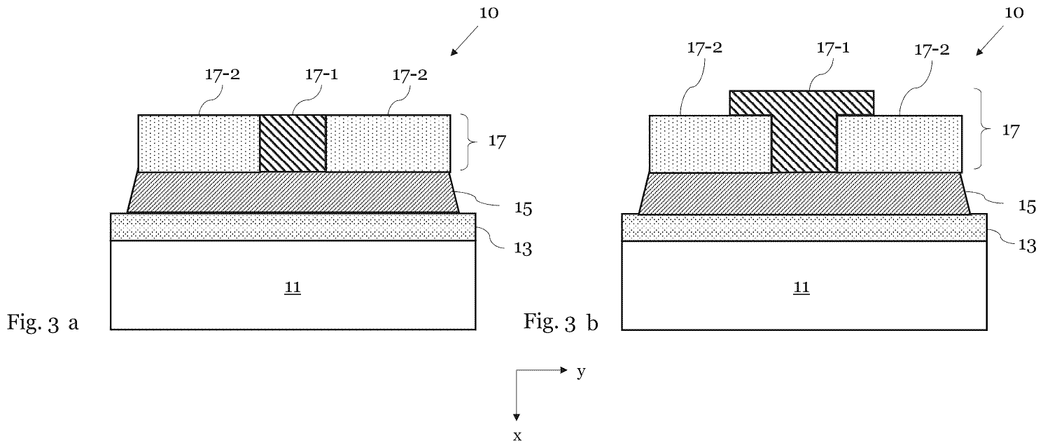

FIGS. 3a-e show schematic diagrams of an FET device according to different embodiments;

FIGS. 4a-b show a perspective view and a top view of an FET device according to an embodiment;

FIG. 5 shows an equivalent circuit diagram of an FET device according to an embodiment;

FIG. 6 shows a chart of the relationship between a gate current of an FET device and interface properties of the respective gate according to an embodiment;

FIGS. 7a-d show top views of a gate area of a FET device according to different embodiments; and

FIGS. 8a-d show steps of a method for fabricating a FET device according to an embodiment.

### DETAILED DESCRIPTION OF EMBODIMENTS

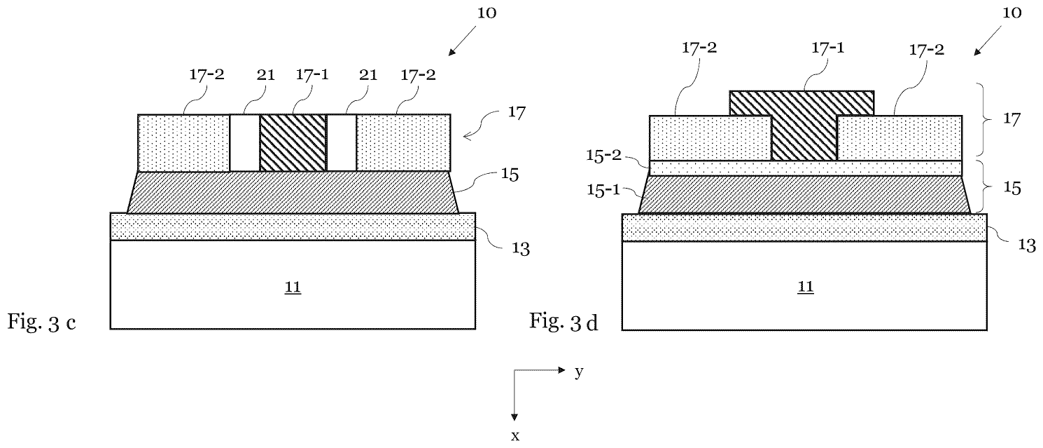

FIGS. 3a-e show schematic diagrams of an FET device 10 according to different embodiments.

The FET device 10, according to the embodiments shown in FIGS. 3a to 3e, comprises a substrate 11, a GaN structure 15 covering a portion of the substrate 11, and a gate metal layer 17 on top of the GaN structure 15. The gate metal layer 17 comprises at least one first section 17-1 being formed from a first material composition, and a second section 17-2 being formed from a second material composition that is different from the first material composition, wherein a first interface between the GaN structure 15 and the at least one first section 17-1 of the gate metal layer 17 has ohmic contact properties, and wherein a second interface between the GaN structure 15 and the second section 17-2 of the gate metal layer 17 has non-ohmic contact properties.

The substrate 11 may comprise a base structure with one or more layers on top. In particular, the substrate comprises an AlGaN top layer 13. The GaN structure 15 can be arranged on top of the AlGaN layer 13.

The substrate 11 can comprise a heteroepitaxial bulk material, e.g. GaN-on-SOI, GaN on sapphire, or GaN-on SiC. The substrate 11 can further comprise a GaN-on-GaN material. In particular, the substrate 11 comprises layers that where formed by an epitaxial growth process.

A channel of the FET device 10 can be formed below the AlGaN layer 13 in a region under the GaN structure, in particular in an interface between the AlGaN layer 13 and an underlying layer of the substrate 11.

Further, source and drain structures of the FET device 10 can be arranged on both ends of the GaN structure 15 (not shown in FIGS. 3a to 3e).

The GaN structure 15 can be a planar layer as shown in FIGS. 3a to 3e or a filling layer, for example in case of a regrowth of the GaN structure 15 in a trench gate.

By employing two different interfaces within one gate, an FET device 10 with a hybrid gate is formed. Such an FET device 10 can have gate properties that combine aspects of an ohmic gate and a non-ohmic gate. For example, the first interface forms an ohmic contact, and the second interface forms a Schottky junction or a p-n junction. The electrical properties of the gate, e.g. gate current, gate reliability or switch-on resistance (Ron), are a combination of the properties of the ohmic and the Schottky or p-n portion of the gate. By controlling the design parameters of these portions, in particular their aspect ratios and/or material compositions, the electrical properties of the gate of the FET device 10 can be adjusted. Hereby, ohmic contact may refer to any contact that behaves like an ohmic contact, i.e. a contact that exhibits the electrical properties of an ohmic contact.

In particular, the interface with ohmic contact properties exhibits a higher leakage current than the interface with the non-ohmic contact properties.

The GaN structure 15 can, further, comprise a p-doped GaN (pGaN) layer. For example, this pGaN layer has a thickness between 50 nm and 1000 nm. In the embodiments shown in FIGS. 3a to 3c, the GaN structure 15 can be formed from this pGaN layer. Via the p-doping, the interface properties between the GaN structure 15 and the gate metal layer 17 can be further adjusted. For example, by adjusting the doping concentration of the pGaN layer a p-n junction at any one of the interfaces can be turned into an ohmic contact.

In particular, the doping of the pGaN layer can be non-uniform. For instance, a concentration of the p-dopants in the pGaN layer is enhanced at the top of the pGaN layer, close to the interface with the gate metal layer 17.

The pGaN layer can be formed from any p-type GaN irrespective of its doping element, e.g. magnesium (Mg), and its method of formation, e.g. metalorganic chemical vapor deposition (MOCVD) growth, molecular-beam epitaxy (MBE) or other deposition techniques.

For example, the first section 17-1 and the second section 17-2 are sub-layers of the gate metal layer 17, wherein each sub-layer has a different material composition.

In particular, the first section 17-1 of the gate metal layer 17 is formed from a first metal stack, and the second section 17-2 of the gate metal layer 17 is formed from a second metal stack. Each metal stack can have a different 40 work function. These metal stacks are contacting the GaN structure 15 to form the first respectively second interface. For example, the first metal stack has an ohmic interface with the GaN structure 15, and the second metal stack has a Schottky interface with the GaN structure 15.

A connection of these metal stacks to higher metal levels of the FET device 10 can be realized through vias or plugs. The vias or plugs can land on either of the metal stacks or on both. The connection can also be realized by a metal layer covering all stacks below.

For example, the first metal stack and/or the second metal stack comprises any one of the following material combinations: Ni/Au, Ni/Ag, Pd/Au, Cr/Au, Pt/Au, Ti/Pt/Au, Ni/Si, W/Si, Ti/A1, Ti/Al/Ti, or TiN/Al/TiN. However, other suitable material combinations are also possible.

Alternative to these metal stacks, the first section 17-1 and/or the second section 17-2 of the gate metal layer 17 can also be formed from single materials, such as indium tin oxide (ITO) or magnesium films/electrodes.

In particular, the least one first section 17-1 being formed from the first material composition means that said first section 17-1 comprises or is formed by the first material composition, e.g. the first metal stack. Likewise, the second section 17-2 being formed from the second material composition means that said second section 17-2 comprises or is formed by the second material composition, e.g. the first metal stack.

Viewed in cross section across the x-y-plane, the edges of the metal stacks can be straight, sloped or V-shaped. The shape of the metal stacks can depend on the metal properties and on etching methods used to fabricate the FET device 10.

In particular, the FET structure 10 can comprise further metal stacks that form the electrical contacts of source and drain terminals (not shown in FIGS. 3a-3e).

In the embodiment shown in FIG. 3a, both sections 17-1, 17-2 of the gate metal layer 17 have the same height. For instance, both sections 17-1, 17-2 are formed from metal stacks with the same thickness.

In contrast, in the embodiment shown in FIG. 3b, the first section 17-1 of the gate metal layer 17 has a bigger thickness than the second section, i.e. the first section protrudes from the second section. The first section 17-1 can, further, partially cover the second section 17-2, i.e. one metal stack extends over the other one. This can make it easier to electrically contact the protruding section.

The two sections 17-1, 17-2 can be self-aligned with each other or to an edge of the GaN structure 15.

In the embodiment shown in FIG. 3c, a separating layer 21 is arranged around the at least one first section 17-1 of the gate metal layer 17. This separating layer 21 physically separates the first section 17-1 from the second section 17-2.

The separating layer 21 can be formed from a non-conductive material, in particular a dielectric. For example, the separating layer is formed from silicon dioxide or a silicon nitride. The separating layer 21 can act as an electrical insulation which insulates the first section 17-1, e.g. a first metal stack, from the second section 17-2, e.g. a second metal stack. This can improve the electrical properties of the gate and facilitate the adjustability of the gate properties via the aspect ratios of the sections 17-1, 17-2.

In the embodiments shown in FIGS. 3d and 3e, the GaN structure 15 comprises an additional n-doped GaN (nGaN) layer 15-2 that is arranged above the pGaN layer 15-1 of the GaN structure 15.

The nGaN layer can be formed from any n-type GaN irrespective of its doping element, e.g. silicon (Si), and its method of formation, e.g. MOCVD growth, MBE or deposition.

In the embodiment shown in FIG. 3d, the nGaN layer 15-2 is arranged below the first section 17-1 and the second section 17-2 of the gate metal layer 17, and in the embodiment shown in FIG. 3e, the nGaN layer 15-2 is only arranged below the second section 17-2 of the gate metal layer 17. It is also possible, that the nGaN layer 15-2 is only arranged below the first section 17-1 or below a portion of the first and/or second section 17-1, 17-2 of the gate metal layer 17.

By adding the nGaN layer 15-2, the electrical properties of the first and/or second interface can be further adjusted. For example, if the nGaN layer 15-2 is arranged below the second section 17-2 of the gate metal layer 17, a Schottky contact formed by the second interface can be changed to a p-n junction.

In addition to the pGaN layer 15-1 and the nGaN layer 15-2, the GaN structure 15 can further comprise an undoped GaN layer. The GaN structure 15 can further comprise multiple pGaN layers 15-1 and/or nGaN layers 15-2. In particular, the GaN structure 15 is formed from a stack of multiple GaN layers.

The nGaN layer(s) 15-2 can be optimized, e.g. via their thickness or doping level, to fulfill target specifications. For example, the n-type doping can be high enough to enhance band bending and create a tunnelling junction. The nGaN layer 15-2 can also be used to convert a Schottky junction to a pn-junction.

In the examples shown in FIGS. 3d and 3e, the first section 17-1 overlaps the second section 17-2. However, this is just an example and FET devices 10 with an nGaN layer 15-2 and non-overlapping sections 17-1, 17-2, such as in FIGS. 3a to 3c, are also possible.

FET devices 10, as shown in FIGS. 3a to 3e, can be used in power semiconductor devices, and, in GaN high electron mobility transistor (HEMT) devices. In particular, the FET device 10 forms a pGaN-gate HEMT, i.e. a GaN HEMT with a gate formed from a pGaN semiconductor to obtain E-Mode (enhanced mode) functionality. Such HEMT devices can be deployed in various different technology fields, such as power supply, automotive, LiDAR, servers, adaptors or DC/DC converters.

In particular, the FET device 10 can form a generic HEMT structure that further comprises a back barrier, multiple conducting channels, multiple barrier thicknesses, recessed AlGaN or recessed pGaN.

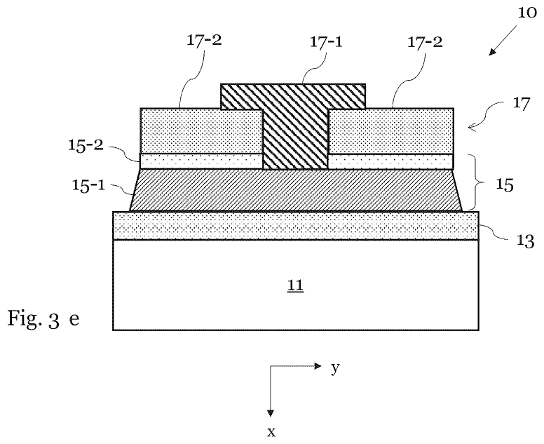

FIGS. 4a-b show a perspective view and a top view of the FET device 10 according to an embodiment.

In the example shown in FIGS. 4a-b, the gate area is divided into two interfaces, wherein the first interface 41 has ohmic contact properties (ohmic interface 41) and the second interface 43 has Schottky contact properties (Schottky interface 43). Thereby, the first interface 41 is the interface between the GAN structure 15 and the first section 17-1 of the metal layer and the second interface 43 is the interface between the GAN structure 15 and the second section 17-2 of the metal layer. For the sake of simplicity, the first and the second section 17-1, 17-2 of the gate metal layer 17 are not shown in FIGS. 4a-b.

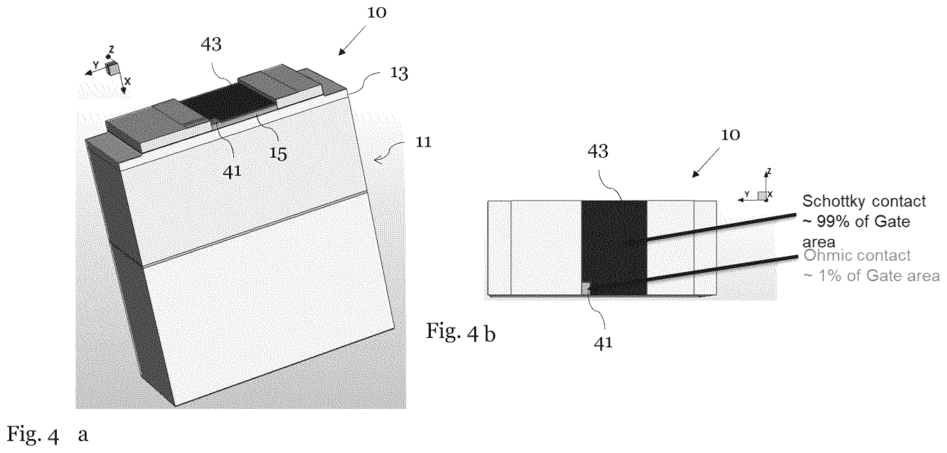

In the example shown in FIGS. 4a and 4b, the FET device 10 has a hybrid gate with −1% of the total gate area being defined as an ohmic contact and the rest as a Schottky contact. The simplified equivalent circuit of such a hybrid gate is depicted in FIG. 5.

The aspect ratio between the first interface 41 and the second interface 43 is adjustable via the aspect ratio of the first and second section 17-1, 17-2 of the gate metal layer 17. In this way, the electrical properties of the gate, in particular the gate current, of the FET device 10 can be adjusted.

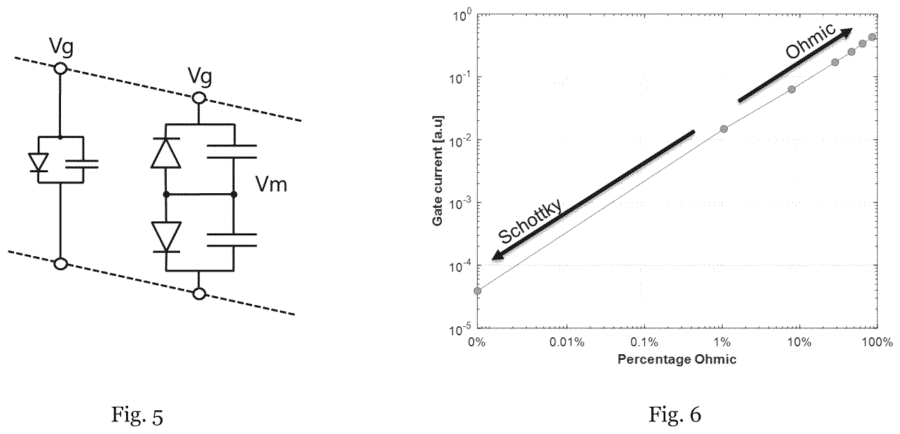

FIG. 6 shows a chart of the relationship between a gate current of the FET device 10 and the interface properties, in particular the aspect ratio between the ohmic interface 41 and the Schottky interface 43, of the respective gate according to an embodiment.

As shown in FIG. 6, adjusting the aspect ratio between the ohmic and Schottky interfaces 41, 43 allows modulating the gate current of the FET device 10. In this way, the gate current level can be controlled by the aspect ratio between two different gate areas.

In particular, reducing the interface area of the ohmic interface 41 (and, thus, increasing the interface area of the Schottky interface 43) leads to a reduction of the gate current, while increasing the interface area of the ohmic interface 41 (and, thus, reducing the interface area of the Schottky interface 43) leads to an increase of the gate current. Therefore, to generate an FET device with a low gate current, the ohmic interface 41, can be designed to make up less than 10%, in particular less than 5%, more particular less than 1% of the total interface area of the gate.

By adjusting the aspect ratios between the ohmic and the Schottky interfaces 41, 43 of the gate, a hybrid (or distributed) gate is formed that can combine the benefits and, at the same time, mitigate the drawbacks of a fully ohmic or a fully Schottky gate. In this way, high voltage (HV) and low voltage (LV) GaN technology platforms can be combined into a single device with the possibility to adjust the specifications of the device by optimizing its layout to fit the needs of a specific product. Hence, resources and time spent to develop multiple technology platforms, e.g. Schottky gate and ohmic gate HEMT devices, can be reduced.

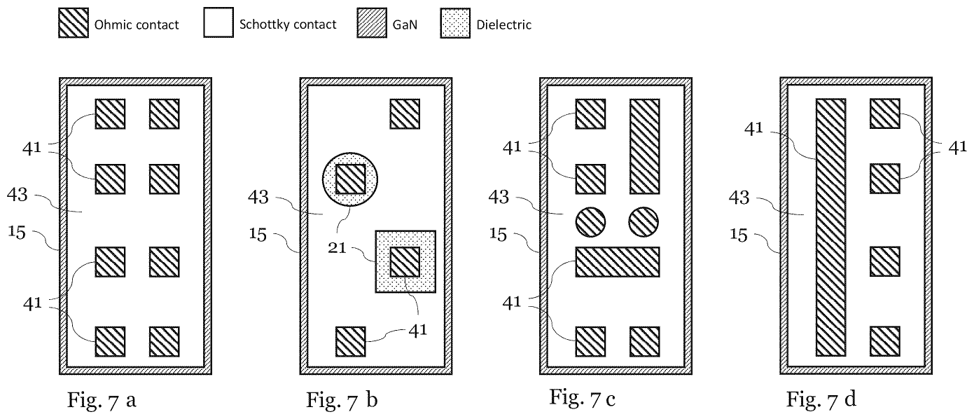

FIGS. 7a-d show top views of a gate area of the FET device 10 according to different embodiments. In particular, FIGS. 7a-d show the interfaces between the GaN structure 15 and the gate metal layer 17 of the FET structure 10. Thereby, the gate metal layer 17 is omitted for the sake of simplicity. The embodiments shown in FIGS. 7a-d represent several possibilities for hybrid, i.e. distributed, ohmic-Schottky gate layouts.

As shown in FIGS. 7a-d, a major gate area can be defined as a Schottky interface 43. Depending on the target aspect ratio, several smaller areas of the gate can be defined as ohmic interfaces 41, or vice versa. Thereby, the ohmic interfaces 41 can be distributed across the gate area. The distributed ohmic interfaces 41 can have different shapes, e.g. square, rectangular, circular, or oval, and different sizes. The ohmic and Schottky interfaces 41, 43 can further be physically separated by the separating layer 21, e.g. a dielectric, as shown in FIG. 7b.

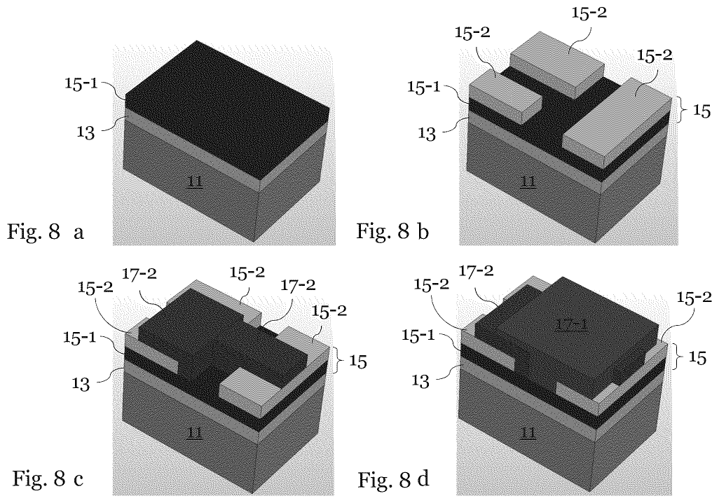

FIGS. 8a-d show steps of a method for fabricating the FET device 10 according to an embodiment.

In a first step, shown in FIGS. 8a and 8b, the substrate 11 is provided and the GaN structure 15 is formed on top of the substrate 11. In particular, the GaN structure 15 can be formed by any suitable deposition technique, such as MOCVD growth or MBE.

The GaN structure 15 can be formed in two steps: first a uniform pGaN layer 15-1 is deposited, as shown in FIG. 8a. Then, a structured nGaN layer 15-2 is formed on top of the pGaN layer 15-1, wherein the structured nGaN layer 15-2 only partially covers the pGaN layer 15-1, as shown in FIG. 8b. The structured nGaN layer 15-2 is, for instance, formed by deposition and subsequent etching or by regrowth.

Alternatively, the nGaN 15-2 deposition can be omitted and the GaN structure 15 can be formed from the uniform pGaN layer 15-1 alone. Also other configurations for the GaN structure 15 are possible, e.g. a uniform nGaN layer on top of the pGaN layer or additional undoped GaN layers.

In a second step, shown in FIGS. 8c and 8d, a first the gate metal layer 17 is formed on top of the GaN structure 15. The gate metal layer 17 comprises at least one first section 17-1 being formed from a first material composition, and a second section 17-2 being formed by a second material composition that is different from the first material composition.

For example, FIG. 8c shows the deposition of the second section 17-2 of the gate metal layer 17 and FIG. 8d shows the deposition of the first section 17-1 on top of the second section 17-2. It is also possible, to form the two sections 17-1, 17-2 in a different order. Each of the two sections 17-1, 17-2 can be formed from a different metal stack that is deposited with a suitable deposition technique. The metals stacks can be made of different material compositions and can have different work function.

The design of the various layers and structures in FIGS. 8a-d is just an example. The same principal method can be used to fabricating the FET device 10 with any one of the designs shown in FIGS. 3a-e and FIGS. 4a-b.

The present disclosure has been described in conjunction with various embodiments as examples as well as implementations. However, other variations can be understood and effected by those persons skilled in the art and practicing the claimed matter, from the studies of the drawings, this disclosure and the independent claims. In the claims as well as in the description the word “comprising” does not exclude other elements or steps and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation.

What is claimed is:

1. A field effect transistor, FET, device (10), comprising:
a substrate (11);
a gallium nitride, GaN, structure (15) covering a portion of the substrate (11);
a gate metal layer (17) on top of the GaN structure (15);
wherein the gate metal layer (17) comprises:
at least one first section (17-1) being formed from a first material composition, and
a second section (17-2) being formed from a second material composition that is different from the first material composition;
wherein a first interface (41) between the GaN structure (15) and the at least one first section (17-1) of the gate metal layer (17) has ohmic contact properties; and
wherein a second interface (43) between the GaN structure (15) and the second section (17-2) of the gate metal layer (17) has non-ohmic contact properties.

2. The FET device (10) of claim 1,
wherein the first interface (41) forms an ohmic contact, and/or
wherein the second interface (43) forms a Schottky junction or a p-n junction.

3. The FET device (10) of claim 1,
wherein the first interface (41) makes up less than 10%, in particular less than 5%, more particular less than 1%, of a total interface area between the GaN structure (15) and the gate metal layer (17), the total interface area comprising the first interface (41) and the second interface (43).

4. The FET device (10) of claim 1,
wherein the gate metal layer (17) comprises a plurality of first sections (17-1) that are separated from each other.

5. The FET device (10) of claim 1,
wherein the gate metal layer (17) comprises a separating layer that is arranged around the at least one first section (17-1) of the gate metal layer (17) to physically separate the first section (17-1) from the second section (17-2) of the gate metal layer (17).

6. The FET device (10) of claim 1,
wherein the at least one first section (17-1) of the gate metal layer (17) has a bigger thickness than the second section (17-2).

7. The FET device (10) of claim 1,
wherein the at least one first section (17-1) of the gate metal layer (17) is formed from a first metal stack, and/or
wherein the second section (17-2) of the gate metal layer (17) is formed from a second metal stack.

8. The FET device (10) of claim 7,
wherein the first metal stack and/or the second metal stack comprises any one of the following material combinations: Ni/Au, Ni/Ag, Pd/Au, Cr/Au, Pt/Au, Ti/Pt/Au, Ni/Si, W/Si, Ti/A1, Ti/Al/Ti, or TiN/Al/TiN.

9. The FET device (10) of claim 1,
wherein the GaN structure (15) comprises a p-doped GaN, pGaN, layer (15-1).

10. The FET device (10) of claim 9,
wherein the GaN structure (15) comprises an n-doped GaN, nGaN, layer (15-2) that is arranged above of the pGaN layer (15-1), wherein the nGaN layer (15-2) at least partially covers the pGaN layer (15-1).

11. The FET device (10) of claim 10,
wherein the nGaN layer (15-2) is arranged above the pGaN layer (15-1) below the first section (17-1) and the second section (17-2) of the gate metal layer (17), such that the first section (17-1) and the second section (17-2) of the gate metal layer (17) are physically separated from the pGaN layer (15-1).

12. The FET device (10) of claim 10,
wherein the nGaN layer (15-2) is only arranged above the pGaN layer (15-1) below the at least one first section (17-1) of the gate metal layer (17), or
wherein the nGaN layer (15-2) is only arranged above the pGaN layer (15-1) below the second section (17-2) of the gate metal layer (17).

13. The FET device (10) of claim 1,
wherein the FET device (10) is a GaN-gate high electron mobility transistor, HEMT, device.

14. Method of fabricating a field effect transistor, FET, device (10), comprising the steps of:
providing a substrate (11);
forming a gallium nitride, GaN, structure on top of the substrate (11),
forming a gate metal layer (17) on top of the GaN structure (15), wherein the gate metal layer (17) comprises at least one first section (17-1) being formed from a first material composition, and a second section (17-2) being formed from a second material composition that is different from the first material composition;
wherein a first interface (41) between the GaN structure (15) and the at least one first section (17-1) of the gate metal layer (17) has ohmic contact properties; and
wherein a second interface (43) between the GaN structure (15) and the second section (17-2) of the gate metal layer (17) has non-ohmic contact properties.

15. The method of claim 14,
wherein the at least one first section (17-1) of the gate metal layer (17) is formed from a first metal stack, and/or
wherein the second section (17-2) of the gate metal layer (17) is formed from a second metal stack.
